(19) United States
(12) Patent Application Publication
(10) Pub. No.: US 2009/0115023 A1
(43) Pub. Date: May 7, 2009

(54) CAPACITOR OF SEMICONDUCTOR DEVICE AND METHOD FOR MANUFACTURING THE SAME

(75) Inventor: Do Hun Kim, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/181,799

(22) Filed: Jul. 29, 2008

(30) Foreign Application Priority Data
Nov. 6, 2007 (KR) 10-2007-0112806

(51) Int. Cl. H01L 29/92; H01L 21/02

(52) U.S. Cl. 257/532; 438/399; 257/E21.008; 257/E29.343

(57) ABSTRACT

A capacitor of a semiconductor device and a method for manufacturing the same. In one example embodiment, a capacitor of a semiconductor device includes a first electrode, first dielectric layer, second electrode, second dielectric layer, and third electrode sequentially formed on a semiconductor substrate. The capacitor also includes a first contact coupled to the first electrode and to the third electrode. The capacitor further includes a second contact coupled to the second electrode.

### CROSS-REFERENCE TO A RELATED APPLICATION

This application claims the benefit of Korean Patent Application No. 10-2007-0112806, filed on Nov. 6, 2007 which is hereby incorporated by reference as if fully set forth herein.

### BACKGROUND

1. Field of the Invention

Embodiments of the present invention relate to a capacitor of a semiconductor device, which can obtain a higher capacitance compared to area by connecting capacitors in parallel, simplify the process of parallel connection of capacitors by using a metal trench, and reduce the area occupied by the semiconductor device, and a method of manufacturing the same.

2. Description of the Related Art

With the recent development of high integration technologies for semiconductor devices, semiconductor devices including logic circuits having analog capacitors integrated thereon have been developed. Analog capacitors used in a logic circuit (for example, a CMOS logic circuit), are mainly divided into polysilicon/insulator/polysilicon (PIP) type capacitors or metal/insulator/metal (MIM) type capacitors.

In a PIP capacitor, the interface between the dielectric and the upper/lower electrodes may be oxidized to form a natural oxide layer because the upper and lower electrodes are made of polysilicon. Such a natural oxide layer may lower the total capacitance of the capacitor.

To obviate these problems, MIM capacitors have been developed. MIM capacitors are widely used in high performance semiconductor devices because they have low specific resistance and no parasitic capacitance due to depletion regions.

A prior art method for manufacturing a capacitor of a semiconductor device will now be described below with reference to the accompanying drawings. FIGS. 1A to 1G are views for sequentially explaining a method for manufacturing a capacitor of a semiconductor device according to the prior art.

As shown in FIG. 1A, a SiN film 12 is deposited as a capping and step layer on a semiconductor substrate 10 where a lower interconnection line 11 is formed. As shown in FIG. 1B, a lower metal film 13, a dielectric layer 14, an upper metal film 15, and a SiN film 16 are next sequentially deposited on the SiN film 12. Thereafter, as shown in FIG. 1C, a lithography and etching process is performed on the lower metal film 13, and then a lithography and etching process is performed on the upper metal film 15, thereby forming a lower electrode 13a, dielectric layer 14a, upper electrode 15a, and SiN film 16a that have a desired width.

As shown in FIG. 1D, an interlayer insulating film 17 is next formed on the entire surface of the resulting material having the lower electrode 13a and the upper electrode 15a, and then planarization is additionally conducted in order to improve the topology of an MIM type capacitor.

As shown in FIG. 1E, first and second contact holes 18 and 19 reaching the lower electrode 13a and the upper electrode 15a, respectively, are formed by a lithography and etching process. As shown in FIG. 1F, after forming the first and second contact holes 18 and 19, a third contact hole 21 reaching the lower interconnection line 11 is formed by a lithography and etching process. Once the first to third contact holes 18, 19, and 21 are formed, these contact holes 18, 19, and 21 are blocked by novolac resin. Then, a lithography and etching process is performed in order to form a trench 22 on the third contact hole 21 and the novolac resin is removed. As shown in FIG. 1G, the SiN films 12 and 16a and the dielectric layer 14a are then etched. Thereafter, Cu is filled in the first contact hole 18, second contact hole 19, third contact hole 21, and trench 22 at the same time by a Chemical Vapor Deposition (CVD) process, thereby forming first and second electrodes 23 and 24 for supplying a voltage and an upper interconnection line 25 having a damascene structure.

The above-described prior art method for manufacturing a capacitor of a semiconductor device includes many mask steps, including a mask step for forming a lower electrode, a mask step for forming an upper electrode, and a key mask for aligning the upper electrode and the lower electrode. The prior art method is also complicated, the cost is high, and the capacitance becomes small.

### SUMMARY OF EXAMPLE EMBODIMENTS

In general, example embodiments of the invention relate to a semiconductor device and a method for manufacturing the same, capable of obtaining a higher capacitance compared to area by connecting capacitors in parallel, facilitating a parallel connection of capacitors by using a metal trench, and reducing the area occupied by the semiconductor device.

In one example embodiment, a capacitor of a semiconductor device includes a first electrode, first dielectric layer, second electrode, second dielectric layer, and third electrode sequentially formed on a semiconductor substrate. The capacitor also includes a first contact coupled to the first electrode and to the third electrode. The capacitor further includes a second contact coupled to the second electrode.

In another example embodiment, a method for manufacturing a semiconductor device includes various steps. First, a first electrode is formed by laminating a first conductive layer on a semiconductor substrate and etching the first conductive layer. Next, a first dielectric layer, second conductive layer, second dielectric layer, and third conductive layer are sequentially laminated on an entire surface on which the first electrode is formed. Then, a third electrode is formed by etching the third conductive layer and the second dielectric layer. Next, a second electrode is formed by etching the second conductive layer and the first dielectric layer. Then, first and second contact holes reaching the first and second electrodes, respectively, are formed. Next, a first trench reaching the third electrode is formed on top of the first contact hole. Then, a second trench is formed on top of the second contact hole. Next, a first contact is formed by filling in the first contact hole and the first trench with a conductive metal. Then, a second contact is formed by filling in the second contact hole and the second trench with a conductive metal.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

Example embodiments of the present invention will be disclosed in the following description of example embodiments given in conjunction with the accompanying drawings, in which:

FIGS. 1A to 1G disclose steps of a prior art method for manufacturing a capacitor of a semiconductor device; and

FIGS. 2A to 2H disclose steps of an example method for manufacturing a capacitor of a semiconductor device.

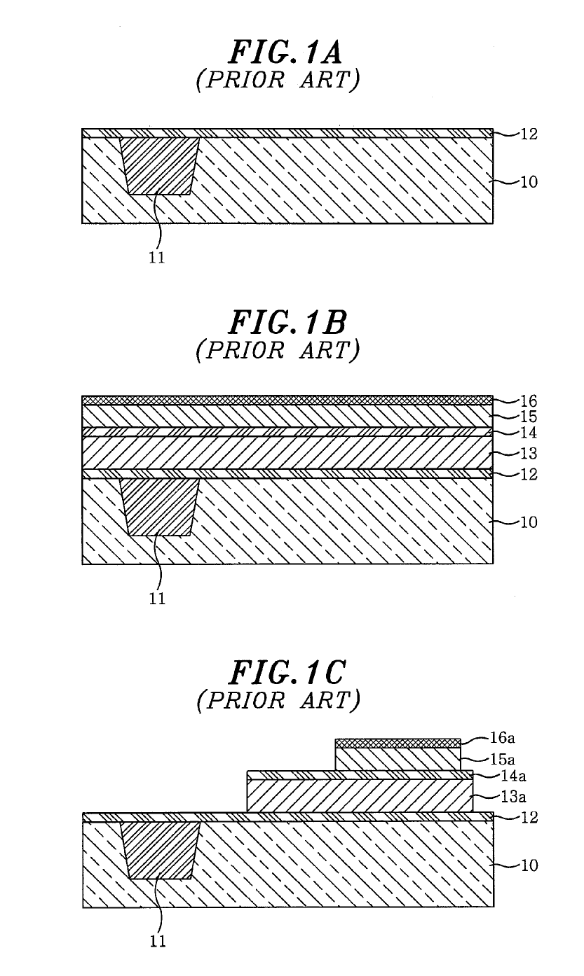

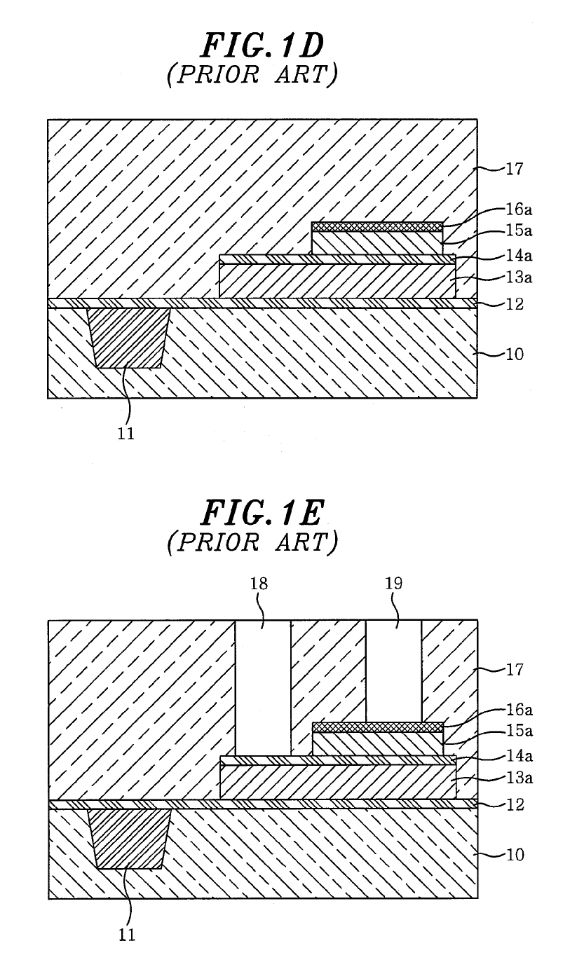

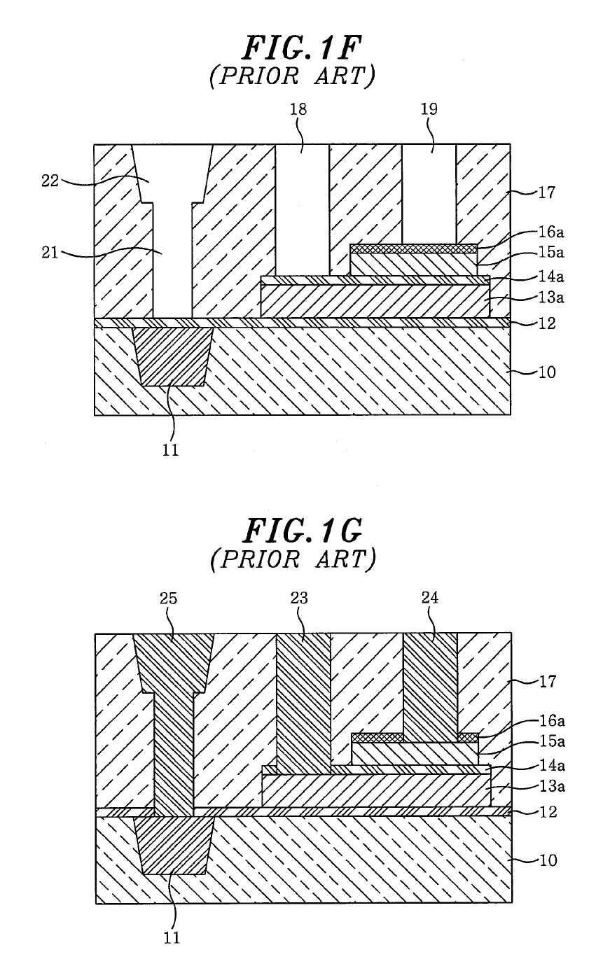

### DETAILED DESCRIPTION OF EXAMPLE EMBODIMENTS

In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

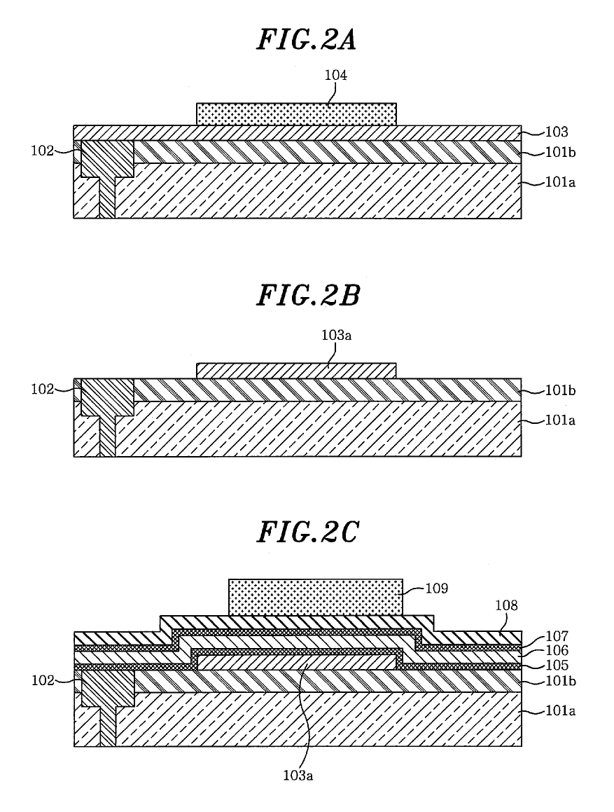

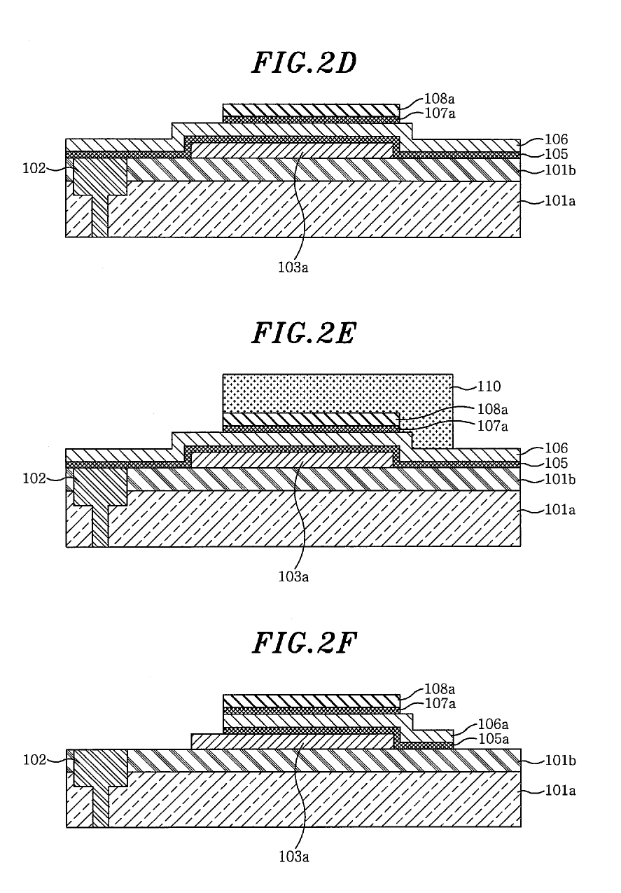

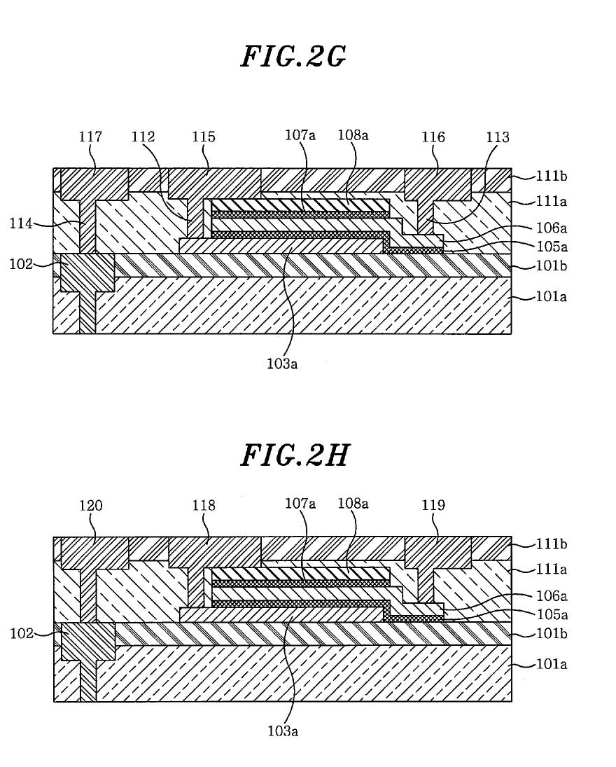

FIGS. 2A to 2H disclose steps of an example method for manufacturing a capacitor of a semiconductor device. As disclosed in FIG. 2H, the example capacitor of the semiconductor device comprises a first electrode 103a, first dielectric layer 105a, second electrode 106a, second dielectric layer 107a, and third electrode 108a sequentially formed on a semiconductor substrate, a first contact 118 reaching the first electrode and the third electrode 108a, and a second contact 119 reaching the second electrode 106a.

As disclosed in FIGS. 2A and 2B, the first electrode 103a is formed by laminating and etching a first conductive layer 104 on the semiconductor substrate, where a lower interconnection line 102 is formed, without any stepped portion in lower insulating films 101a and 101b.

As disclosed in FIGS. 2C and 2D, the second dielectric layer 107a and the third electrode 108a are formed by etching the second dielectric layer 107 and third conductive layer 108, which are sequentially laminated on the first conductive layer 105 and second conductive layer 106.

As disclosed in FIGS. 2E and 2F, the first dielectric layer 105a and the second electrode 106a are formed by etching the first dielectric layer 105 and the second conductive layer 106. The first dielectric layer 105a and second electrode 106a are formed so as to deviate from one side of the top surface of the first electrode 103a.

As disclosed in FIG. 2G, this deviation from one side of the top surface of the first electrode 103a enables the formation of a first contact hole 112 reaching the first electrode 103a. The first dielectric layer 105a and of the second electrode 106a extend beyond the other side of the top surface of the first electrode 103a, thereby forming a parallel capacitor structure. The second dielectric layer 107a and the third electrode 108a are formed so as to deviate from a portion of the top surface of the second electrode 106a, thereby enabling the formation of a second contact hole 113 reaching the second electrode 106a. The first, second, and third electrodes 103a, 106a, and 108a are made of a conductive metal such as copper (Cu), for example.

As disclosed in FIGS. 2G and 2H, the first contact 118 is formed by filling the first contact hole 112 and a trench 115 with a conductive metal, such as copper (Cu) or tungsten (W). The first contact 118 reaches the first electrode 103a and the third electrode 108a. The second contact 119 is formed by filling the second contact hole 113 and a trench 116 with a conductive metal, such as copper (Cu) or tungsten (W).

As disclosed in FIG. 2H, the first electrode 103a, first dielectric layer 105a, and second electrode 106a constitutes one capacitor, and the second electrode 106a, second dielectric layer 107a and third electrode 108a constitutes another capacitor. Since these capacitors have a parallel connection structure, capacitance is increased.

An example process for manufacturing the example capacitor of the semiconductor device described above will now be disclosed.

As disclosed in FIG. 2A, a first conductive layer 103 is formed by deposition on a semiconductor substrate, in which a lower interconnection line 102 is formed, without any stepped portion in lower insulating films 101a and 101b constituting a multilayer. A photoresist pattern 104 for defining a first electrode is formed on the first conductive layer 103 by a lithography process, and, as disclosed in FIG. 2B, a first electrode 103a is formed by an etching process using the photoresist pattern 104.

Also disclosed in FIG. 2C, a first dielectric layer 105, second conductive layer 106, second dielectric layer 107, and third conductive layer 108 are sequentially deposited on the entire surface of the resulting material. Next, a photoresist pattern 109 for defining a third electrode is formed by a lithography process. As disclosed in FIG. 2D, a third electrode 108a is formed by an etching process using the photoresist pattern 109.

As disclosed in FIG. 2E, a photoresist pattern 110 for defining a second electrode is formed by a lithography process on the second conductive layer 106, the third electrode 108a, and the second conductive layer 107a. As disclosed in FIG. 2F, the second electrode 106a is formed by an etching process using the photoresist pattern 110. The second conductive layer 107a and the third electrode 108a are formed so as to deviate from a portion of the top surface of the second electrode 106a, thereby enabling the formation of a second contact hole 113 reaching the second electrode 106a.

Further, the first dielectric layer 105a and second electrode 106a deviate from one side of the top surface of the first electrode 103a, thereby enabling the formation of a first contact hole 112 reaching the first electrode 103a. The first dielectric layer 105a and second electrode 106a extends beyond the other side of the top surface of the first electrode 103a, thereby forming a parallel capacitor structure. The first to third electrodes 103a, 106a, and 108a are made of a conductive metal such as copper (Cu), for example.

As disclosed in FIG. 2G, multilayer insulating films 111a and 111b are sequentially formed on the entire surface of the resulting material Next, a first contact hole 112 and a second contact hole 113 reaching the first electrode 103a and the second electrode 106a, respectively, are formed by etching the insulating films 111a and 111b. Then, a third contact hole 114 reaching the lower interconnection line 102 is formed. Next, a first trench 115 reaching the third electrode 108a is formed on top of the first contact hole 112 by a lithography and etching process. A second trench 116 and a third trench 117 are formed by a lithography and etching process, simultaneously with or subsequent to the formation of the second contact hole 113 and third contact hole 114.

As disclosed in FIGS. 2G and 2H, a first contact 118 having a damascene structure reaching the first electrode 103a and third electrode 108a and a second contact 119 having a damascene structure reaching the second electrode 106a are formed by filling a conductive metal, such as copper (Cu) and tungsten (W) for example, by Chemical Vapor Deposition (CVD) in the first contact hole 112 and first trench 115 and in the second contact hole 113 and second trench 116, respectively. Thereafter, an upper interconnection line 120 is formed on the lower interconnection line 102 by filling in the third contact hole 114 and third trench 107 with a conductive metal, such as copper (Cu) and tungsten (W) for example, by Chemical Vapor Deposition (CVD).

As disclosed above, an interconnection process for connecting two capacitors in parallel is employed by using a dual damascene process. No particular routing for connecting the first electrode 103a and the third electrode 108a is performed. Instead, the trench portion 115 of the first contact 118 is connected to the third electrode 108a during the dual damascene process.

In accordance with embodiments of the present invention as described above, the capacitor of the semiconductor device and the method for manufacturing the same can obtain a higher capacitance compared to area by connecting capacitors in parallel by laminating a structure consisting of a conductive layer, a dielectric layer, and a conductive layer, simplify the process of parallel connection of capacitors by using a metal trench, and reduce the area occupied by the semiconductor device.

Although example embodiments of the present invention have been shown and described, changes might be made in these example embodiments. The scope of the invention is therefore defined in the following claims and their equivalents.

What is claimed is:

1. A capacitor of a semiconductor device, comprising:
a first electrode, first dielectric layer, second electrode, second dielectric layer, and third electrode sequentially formed on a semiconductor substrate;
a first contact coupled to the first electrode and to the third electrode; and
a second contact coupled to the second electrode.

2. The capacitor of claim 1, wherein the first dielectric layer and the second electrode are extended beyond a top surface of the first electrode.

3. The capacitor of claim 1, wherein the first contact is formed to have a damascene structure.

4. The capacitor of claim 1, wherein the second contact is formed to have a damascene structure coupled to the second electrode.

5. A method for manufacturing a semiconductor device, comprising:
forming a first electrode by laminating a first conductive layer on a semiconductor substrate and etching the first conductive layer;
sequentially laminating a first dielectric layer, second conductive layer, second dielectric layer, and third conductive layer on an entire surface on which the first electrode is formed;
forming a third electrode by etching the third conductive layer and the second dielectric layer;
forming a second electrode by etching the second conductive layer and the first dielectric layer;
forming first and second contact holes reaching the first and second electrodes, respectively;
forming a first trench reaching the third electrode on top of the first contact hole;
forming a second trench on top of the second contact hole;
forming a first contact by filling in the first contact hole and the first trench with a conductive metal; and
forming a second contact by filling in the second contact hole and the second trench with a conductive metal.

6. The method of claim 5, wherein the second electrode, the first dielectric layer and the second electrode extend beyond a top surface of the first electrode.

7. The method of claim 5, wherein the first contact has a damascene structure.

8. The method of claim 7, wherein forming the first contact comprises filling in the first contact hole and the first trench with a conductive metal by Chemical Vapor Deposition (CVD).

9. The method of claim 5, wherein the second contact has a damascene structure.

10. The method of claim 9, wherein forming the second contact comprises filling in the second contact hole and the second trench with a conductive metal by Chemical Vapor Deposition (CVD).
